(19) United States
(12) Patent Application Publication
(10) Pub. No.: US 2011/0050273 A1
(43) Pub. Date: Mar. 3, 2011

(54) FAST TESTABLE WAFER AND WAFER TEST METHOD

(75) Inventor: Ssu Pin Ma, San Jose, CA (US)

(73) Assignee: Ssu-Pin Ma, San Jose, CA (US)

(21) Appl. No.: 12/547,268

(22) Filed: Aug. 25, 2009

(51) Int. Cl. G01R 1/06; G01R 31/26; G01R 31/02

(52) U.S. Cl. 324/762.05

(57) ABSTRACT

A fast testable wafer includes a die group, testing points located on dies, a scribe line located between the dies, and a plurality of testing pads disposed in the scribe line area. The testing points comprise bonding pads or electrodes of internal circuits within the dies. The testing pads and bonding pads may be electrically connected and arranged suitably such that testing probes may be electrically connected to the testing pads and bonding pads easily so as to test the plurality of dies at about the same time. Through suitable circuits on the wafer, different circuit routes may be selected to connect the testing pads and different testing points on the dies so as to test a plurality of dies without moving the testing probes and thereby accelerating the test.

### FIELD OF INVENTION

Various embodiments of the invention relates to a wafer and wafer test method, and more particularly to a fast testable wafer and wafer test method.

### BACKGROUND

The first integrated circuit appeared about half a century ago. With the development of science and technology, various integrated circuit technologies keep emerging. According to the progress of the development history of integrated circuits, it is found that the number of transistors that can be accommodated on an integrated circuit of the same area doubles about every eighteen months. Such a phenomenon is referred to as Moore's Law. Moore's Law provides an important observation index. That is, the integrated circuits are exponentially developed. With the rapid development of integrated circuits, various technologies applicable to integrated circuits appear accordingly, such as microprocessors and digital signal processors. These technological products applying integrated circuits also give rise to subsequent information revolution, thus bringing changes to the current world.

Wafers are used as carriers for fabrication during the production of integrated circuits. After semiconductor fabrication processes, a plurality of dies is formed on a wafer. These dies are sawn and packaged to form the common integrated circuits. The wafers may be categorized according to their diameters, such as four inches, five inches, six inches, and eight inches. Currently, 12 inches or even larger sizes are made an appearance. The wafer of a larger size has more dies accordingly. Thus, when integrated circuits are produced, using larger size dies as carriers for production reduces an average cost of each integrated circuit. In addition, according to different process technologies, the number of dies that can be formed on a wafer of the same size may also be different. For example, when a 45-nanometer process technology is used, the dies formed on a wafer of the same size may be about twice as many as those when a 60-nanometer manufacturing process technology is used.

After a wafer is produced, every die on the wafer needs to be tested to ensure the normal function of the die. However, when more dies are formed on the same wafer, longer time is needed for testing the wafer. According to Moore's Law, the integrated circuits are developed exponentially. As all dies are usually tested one by one in current methods, it may be properly concluded that the testing time of a wafer also increases greatly accordingly. The testing time consumption may greatly delay time-to-market of a product. For manufacturers, time-to-market delay of a product may cause a huge loss.

### SUMMARY

Various embodiments of the invention are directed to a method and an apparatus for wafer testing.

In the single embodiment or in some embodiments, a fast testable wafer comprises a plurality of dies, at least a scribe line area, and a plurality of testing pads. At least one die comprises a plurality of testing points. The testing point may be a bonding pad or an electrode of an internal circuit within the die. The electrode of an internal circuit could be an internal electrode which may be not necessarily exposed to be probed from outside. When an individual die may be separated from other dies on the wafer, wafer sawing may be performed on the wafer along the scribe line. The plurality of testing pads may be disposed in the scribe line area. At least one of the testing points of at least one die may be electrically connected to at least one of the testing pad.

In the single embodiment or in some embodiments, the testing pads may be located in one row or multiple rows.

In the single embodiment or in some embodiments, the fast testable wafer comprises a plurality of bonding pads which may be not electrically connected to the testing pads and may be arranged to be a row or multiple rows. At least one of these bonding pads and at least one of the testing pads may be arranged to be contacted by the testing probe during the test.

In the single embodiment or in some embodiments, only some or all of the testing pads may be arranged to be contacted by the testing probes during the testing process.

In the single embodiment or in some embodiments, the testable wafer further comprises at least one isolating element. The isolating element is electrically connected between one of the testing pads and one of the testing points. The isolating element may be an isolator or a buffer amplifier.

In the single embodiment or in some embodiments, the testable wafer comprises at least one die group, a plurality of bonding pads, at least one scribe line area, and a plurality of testing pads disposed in the scribe line area. The at least one die group comprises a plurality of dies. The at least one die comprises a plurality of testing points. The scribe line area used for separating at least two of the plurality of dies. At least one of the plurality of testing pads is electrically connected to at least one of the plurality of testing points through the at least one electronic switch module.

In the single embodiment or in some embodiments, at least one die group comprises a plurality of dies. At least one die comprises a plurality of testing points. At least one testing point of at least one die may be electrically connected to at least one electronic switch module and at least one address decoder. The address decoder may be used for outputting a signal to control the electronic switch module.

In the single embodiment or in some embodiments, at least one testing point of at least one die in the same die group may be electrically connected to the testing pad with a switch module interposed in between.

In the single embodiment or in some embodiments, at least one of the bonding pads or at least one of the testing pads may be the path of the address signals. The at least one of the bonding pads may be electrically connected to the at least one address decoder.

In the single embodiment or in some embodiments, at least one address decoder in a group of the die group may be assigned at least one address. With the address signal transmitted, at least one testing pad will connect to at least one testing point which may be electrically connected to at least one electronic switch module and at least one address decoder to which that address may be assigned.

In the single embodiment or in some embodiments, a plurality of address decoders of the die group may be assigned at least one group address. With a group address signal transmitted, at least one testing pad will connect to a plurality of testing points in a plurality of dies which may be electrically connected to at least one electronic switch module and at least one address decoder which may be assigned that group address.

In the single embodiment or in some embodiments, at least one die may be operatively connected at least one address decoder, and there may be at least one testing point of at least one die which may be electrically connected to a testing pad with a switch module interposed in between. The output of the address decoder may be connected to the switch module. When the address decoder may be selected by transmitted the address signal, the group address signal, or the sub-group address signal, the switch module may be closed. When the address decoder may be neither selected by transmitted the address nor the sub-group address signal, the switch module will be opened. Here we said an address decoder may be selected means an address signal, or a group address signal, or a sub-group address signal which corresponds to the address, or the group address, or the sub-group address of the address decoder may be transmitted to the address decoder.

In the single embodiment or in some embodiments, the fast testable wafer has at least one address decoder with at least two outputs, and there exists at least one testing point of at least one die may be electrically connected to a testing pad with a switch module interposed in between. At least one output of the address decoder may be connected to the switch module. The output of the address decoder may correspond to at least one address, or at least one group address, or at least one sub-group address. When the output of the address decoder may be selected by transmitted the address signal or the group address signal, or the sub-group address signal, the switch module may be closed. When the output of address decoder may not be selected by transmitted the address signal, or the group address signal, or the sub-group address signal, the switch module may be opened.

In the single embodiment or in some embodiments, the fast testable wafer comprises a fast testable wafer or a use thereof, which fast testable wafer comprises at least one address decoder, at least one switch module, and there exists at least one testing pad which may be connected to a testing point or a plurality of testing points without connecting through a switch module or switch modules.

In the single embodiment or in some embodiments, the fast testable wafer comprises at least one die group, at least one scribe line area, and a plurality of testing pads.

In the single embodiment or in some embodiments, at least one die group comprises a plurality of dies and at least one multiplexer. At least one die comprises a plurality of testing points. The multiplexer comprises a plurality of output ports. At least one output port may be electrically connected to at least one testing point of at least one die.

In the single embodiment or in some embodiments, the multiplexer provided the electrical connections between testing pads and testing points.

In the single embodiment or in some embodiments, with a particular address signal, at least one testing point which may correspond to that address may be electrically connected to a testing pad through a multiplexer.

In the single embodiment or in some embodiments, the fast testable wafer comprises at least one switch module and at least one isolator or at least one buffer which may be electrically connected in between at least one testing pad and at least one testing point.

One embodiment further provides a fast wafer test method applicable to a wafer. The wafer comprises a plurality of dies, a scribe line area, and at least one testing pads located in the scribe line area, a plurality of testing points. During test, a test instrument may be connected to the testing pads through testing probes. The test instrument generates at least one test signal to a testing point or a testing point group for test. In the single embodiment or in some embodiments, the act of selecting comprises providing a suitable electrical path with the circuits on the wafer such that the test instrument may be connected to the specific testing point group through the testing pads. The test instrument may test a plurality of dies or different testing points on the dies by changing different address signals.

In the single embodiment or in some embodiments, the testing may be performed sequentially. The testing probes may be moved after the testing procedures of a group die may be completed.

In the single embodiment or in some embodiments, the method or the apparatus may test multiple dies at about the same time with selections of sub-group address or with some test pints in different dies may be directly electronically connected to testing pads. With respect to the term “at about the same time”, one of ordinary skill in the art will certainly appreciate the fact that no two dies may practically or scientifically receive or transmit signals exactly the same time even though the two dies are designed or intended to receive or transmit signals at exactly the same time due to the inevitable lag caused by, for example, timing delay or electronic signal transmission delay from or to the two dies.

In the single embodiment or in some embodiments, bonding pads of a die not connected to the plurality of testing pads and the testing pads may be arranged in an array. This configuration enables a group of testing probes to measure signals of the wafer conveniently and rapidly. In addition or in the alternative, the address decoders or multiplexers may be disposed in the wafer. Where a plurality of dies may be measured, the dies to be tested may be selected according to address signals. Thus, the plurality of dies may be tested without moving the group of testing probes. In the single embodiment or in some embodiments, as the time for mechanically moving the group of testing probes may be longer than that for electrical switching, the method or the apparatus substantially reduces the required time for wafer test.

### BRIEF DESCRIPTION OF THE DRAWINGS

The invention will become more fully understood from the detailed description given herein below for illustration only, and thus may be not limitative of the invention, and wherein:

FIGS. 1A, 1B, and 1C illustrate schematic block views according to a first embodiment of the invention;

FIGS. 2A 2B and 2C illustrate schematic views of connection relations according to the first embodiment of the invention;

FIG. 3 illustrates a schematic block view according to a second embodiment of the invention;

FIGS. 4A and 4B illustrate schematic block views according to a third embodiment of the invention;

FIG. 5A illustrates a schematic view of a connection relation between an address decoder and an electronic switch module according to the invention;

FIG. 5B illustrates a schematic view of a structural connection relation of an electronic switch module according to the invention;

FIG. 6 illustrates a schematic block view according to a fourth embodiment of the invention;

FIG. 7 illustrates a schematic block view according to a fifth embodiment of the invention;

FIG. 8A and 8B illustrates a schematic view of a multiplexer according to the invention;

FIG. 9A illustrates a schematic block view according to a sixth embodiment of the invention;

FIG. 9B illustrates a schematic block view according to a seventh embodiment of the invention;

FIG. 9C illustrates a schematic block view according to a eighth embodiment of the invention;

FIG. 10 illustrates a flow chart of a test method according to a first embodiment of the test method of the invention;

FIGS. 11A and 11B illustrate flow charts of a test method according to a second embodiment of the test method of the invention;

FIG. 12 illustrates a flow chart of a test method according to a third embodiment of the test method of the invention; and

FIG. 13 illustrates a flow chart of a test method according to a fourth embodiment of the test method of the invention.

### DETAILED DESCRIPTION

The detailed features and advantages of the invention may be described below through the following embodiments, and the content of the detailed description is sufficient for persons skilled in the art to understand the technical content of the invention and to implement the invention accordingly. Based upon the content of the specification, the claims, and the drawings, one of ordinary skill in the art can easily understand the relevant objectives and advantages of the invention. The following illustrations and examples may be intended to describe various embodiments of the invention in further details but may not be intended to limit the scope of various embodiments in any way.

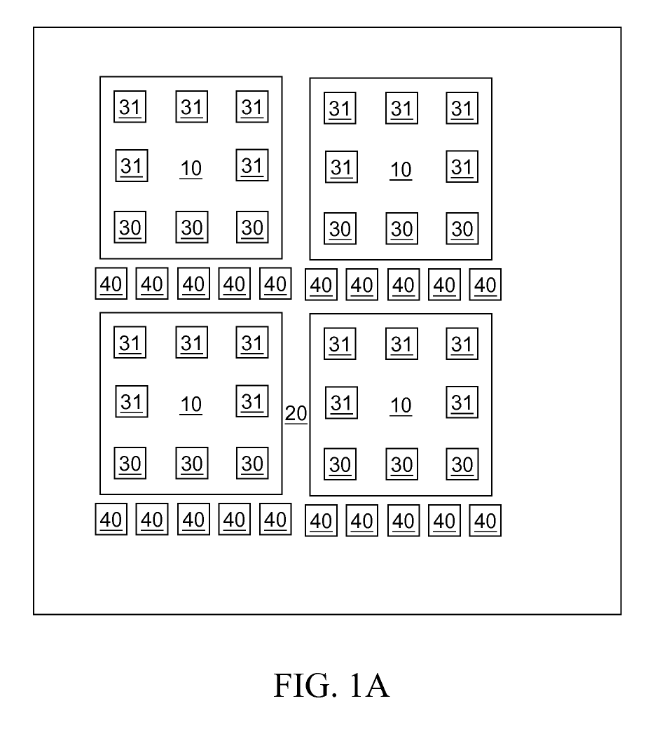

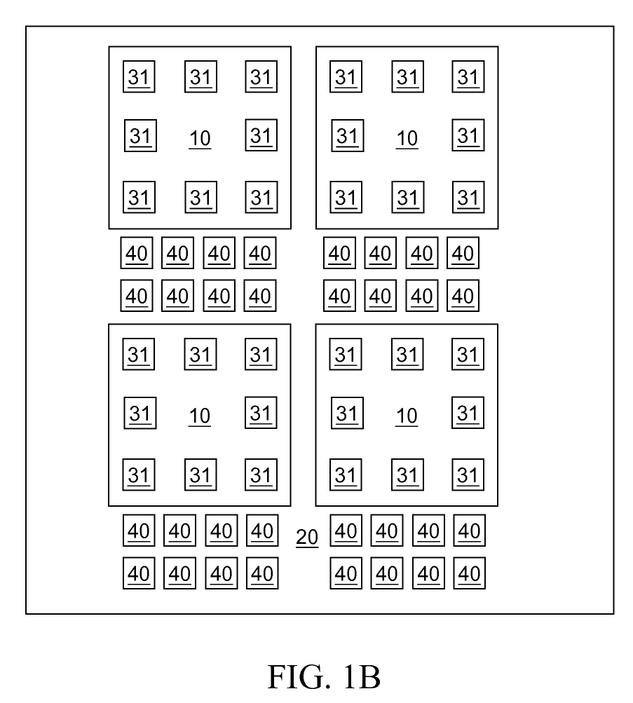

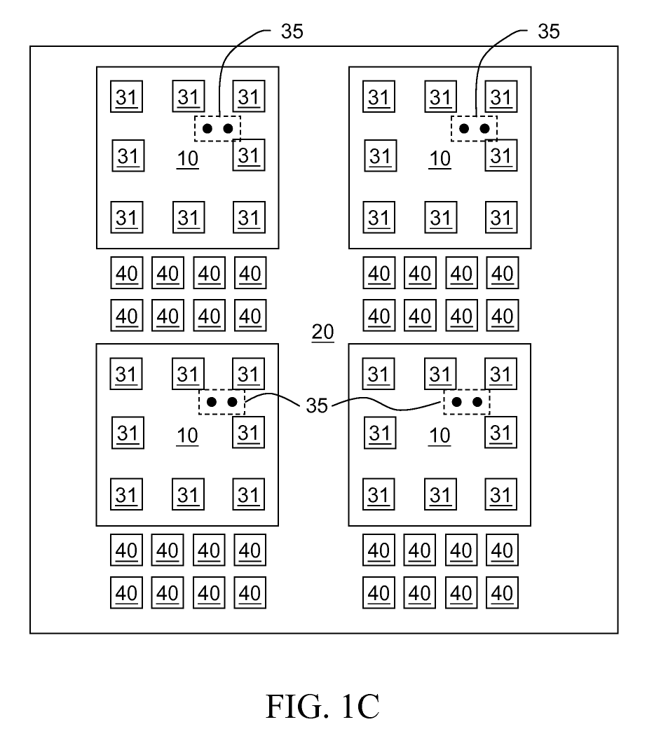

FIGS. 1A and 1B illustrate schematic views of a fast testable wafer according to a first embodiment of the invention. The wafer comprises a plurality of dies 10, a scribe line area 20, and a plurality of testing pads 40.

In the single embodiment or in some embodiments, a scribe line area comprises the areas of wafer that are not utilized or occupied by the dies.

In the single embodiment or in some embodiments, a scribe line area comprises the areas of a wafer that are not utilized or occupied by the dies less the edge exclusion on the device side of the wafer. In the single embodiment or in some embodiments, a scribe line area comprises the areas of a wafer that are not utilized or occupied by the dies minus the area on the back side of the wafer and the area(s) of the edge exclusion on the device side of the wafer. One of the purposes of a scribe line area may be for separating the dies. When an individual die may be separated from other dies on the wafer, wafer sawing may be performed on the wafer along the scribe line.

In the single embodiment or in some embodiments, a testing pad may be a pad disposed in the scribe line area.

In FIG. 1A, the dies 10 maybe arranged in an array. Each die 10 comprises a first group of bonding pads 30 and a second group of bonding pads 31. The scribe line area 20. The testing pads 40 may be disposed in the scribe line area 20. In this embodiment, four dies 10 may be taken for example; however, the number of the dies 10 may not be so limited in various embodiments of the invention. Furthermore, the arrangement of the dies 10 need not be limited to an array.

In the single embodiment or in some embodiments, a bonding pad may be a pad disposed in a die.

In the single embodiment or in some embodiments, a bonding pad may be a pad disposed in a die for bonding purpose or for probing purpose.

The first group of bonding pads 30 and the second group of bonding pads 31 may be used for providing interfaces for individual dies to transmit or receive signals. The first group of bonding pads 30 of the die 10 may not be connected to the testing pads 40. The second group of bonding pads 31 of the die 10 may be electrically connected to the testing pads 40 respectively. FIG. 1B illustrates a schematic view of a fast testable wafer according to another embodiment of the invention. The die 10 comprises the second group of bonding pads 31. The second group of bonding pads 31 of the die 10 may be electrically connected to the testing pads 40 respectively. In this embodiment, the number of the testing pads 40 may be the same as the total number of the bonding pads on the dies 10.

Referring to FIG 1C, besides that the second group of bonding pads 31 may be connected to the testing pads 40, an electrode of an internal circuit 35 in the die 10 may be electrically connected to the testing pads 40 in the single embodiment or in some embodiments. The electrode of an internal circuit 35 in the die 10, which may be usually difficult to measure, may be tested through the testing pads 40. Therefore, the number of the testing pads 40 may be greater than a total number of the bonding pads (the first groups of bonding pads 30 or the second groups of bonding pads 31) on the dies 10.

In the single embodiment or in some embodiments, the number of the testing pads 40 may be larger than, equal to, or smaller than the number of the bonding pads on the dies 10.

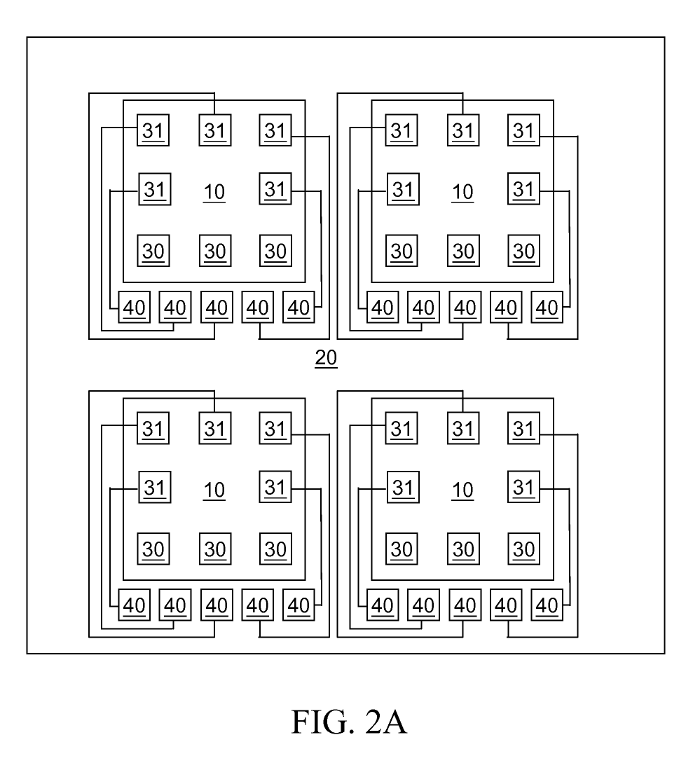

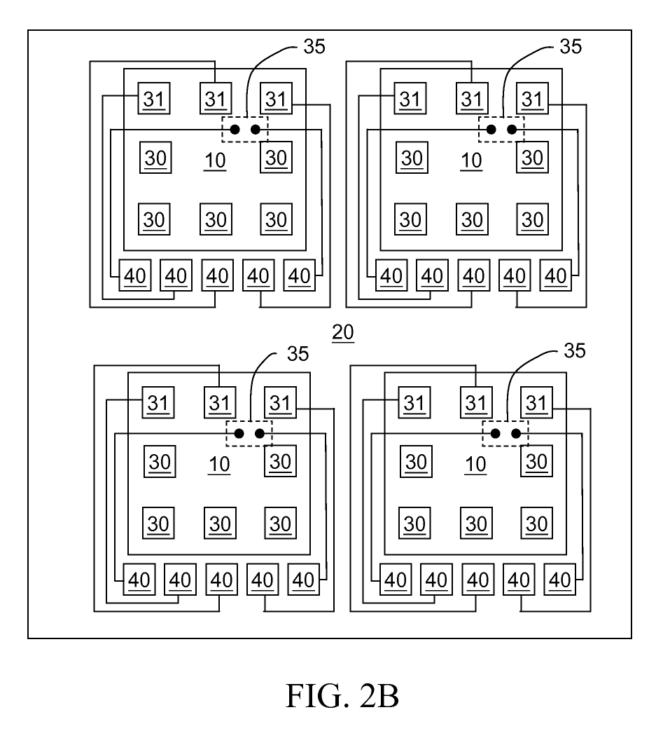

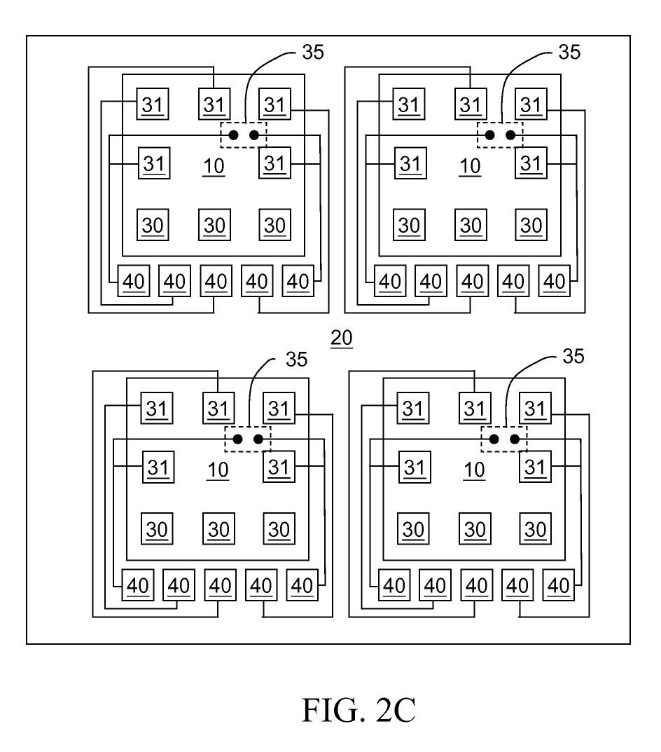

FIG. 2A shows connection relations between the second group of bonding pads 31 and the testing pads 40. The wafer comprises a plurality of metal layers. Different metal layers in the wafer respectively serve as channels for electrical connection between the second group of bonding pads 31 and the testing pads 40. The second group of bonding pads 31 may be electrically connected to the testing pads 40 in a one-to-one relationship. In FIG. 2B, the testing pads 40 may be electrically connected to the second group of bonding pads 31 and the electrodes of internal circuits 35. The bonding pads 31 and the electrodes of internal circuits 35 are generally called as testing points.

In this embodiment, the second group of bonding pads 31 may be arranged in a one-dimensional array. The testing pads 40 may also be arranged in a one-dimensional array. Here, the one-dimensional array indicates that components in this array may be located at the same straight line or approximately at one straight line, while the interval may not be limited to the same. During measurement, each die 10 may be rapidly measured with a group of testing probes in an arrangement corresponding to that of the second group of bonding pads 31 and the testing pads 40.

In the single embodiment or in some embodiments, the second group of bonding pads 31 may be arranged in one, two or even more rows. However, this technology may be known to persons of ordinary skill in the art, and will not be described in detail here.

In FIG. 2C, a part of testing pads 40 may be electrically connected to the plurality of testing points in a one-to-many relationship. The plurality of testing points may be on the same die or on a plurality of dies.

In the single embodiment or in some embodiments, the testing point may be a bonding pad 30, 31 or an electrode of internal circuit 35 within the die. The electrode of internal circuit 35 could be an internal electrode which may not be necessarily exposed to be probed from outside.

As depicted in FIG. 2A, 2B and 2C, the connection relationship between the testing pads 40 and the testing points may be implemented in different ways. In the single embodiment or in some embodiments, at least one of the testing pads 40 may be operatively connected to a plurality of testing points in a plurality of dies 10 according to Attorney Docket No.: 15042-72339 a one-to-many relationship. In the single embodiment or in some embodiments, at least one of the testing pads 40 may be operatively connected to testing points of a same die 10 according to a one-to-many relationship. In the single embodiment or in some embodiments, at least two of the testing pads 40 may be operatively connected to a single testing point according to a many-to-one relationship.

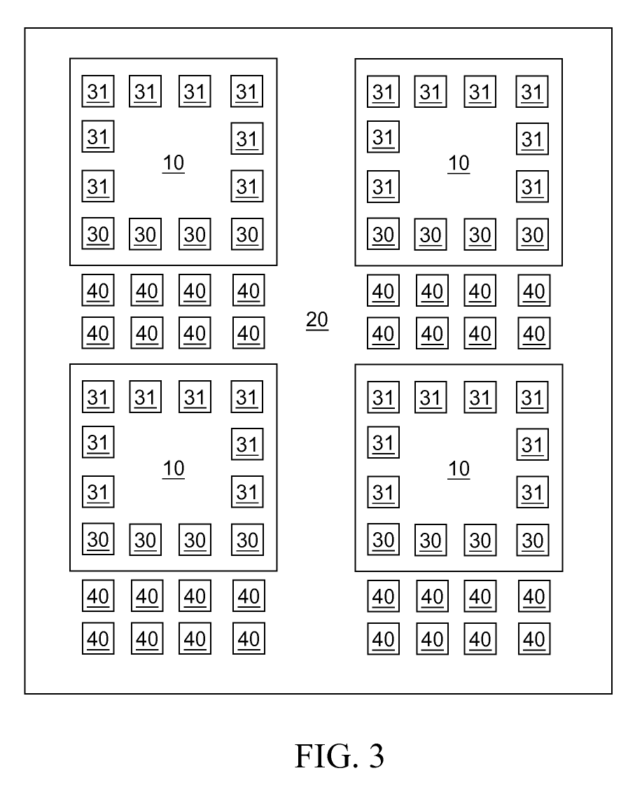

FIG. 3 illustrates a schematic view of a fast testable wafer according to a second embodiment of the invention. The wafer comprises dies 10, a scribe line area 20, and testing pads 40.

A first group of bonding pads 30 of the die 10 may not be connected to the testing pads 40. A second group of bonding pads 31 of the die 10 may be electrically connected to the testing pads 40 respectively. For simplicity of FIG. 3, the above connection relations are not shown. One of ordinary skill in the art may select a suitable method to connect the second group of bonding pads 31 and the testing pads 40 according to the concept and the spirit disclosed in this embodiment. In this embodiment, the second group of bonding pads 31 and the testing pads 40 may be together arranged in a two-dimensional array. In this embodiment, the two-dimensional array indicates that the components in this array may be arranged in columns and rows, and the columns and rows may be a one-dimensional array respectively. During measurement, a plurality of dies 10 may be rapidly measured with a group of testing probes in an arrangement corresponding to that of the second group of bonding pads 31 and the testing pads 40.

In FIG. 3, the testing pads 40 may be arranged in two rows at equal spacing. The testing pads 40 may be arranged to provide suitable contact with the probes. Thus, as long as probe contact may not be obstructed, in other embodiments, the testing pads 40 may be arranged at unequal intervals. As long as the probe contact may be not obstructed, each row of the testing pads 40 need not be arranged completely along a straight line in the single embodiment or in some embodiments. As long as the probe contact may not be obstructed, the testing pads 40 may be arranged in a plurality of rows, and the rows may be arranged at specific displacement in the single embodiment or in some embodiments.

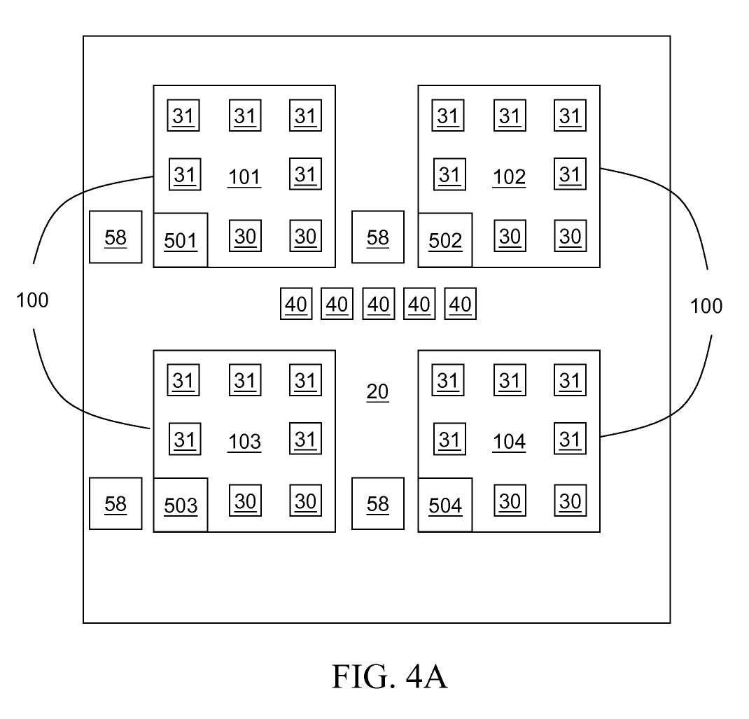

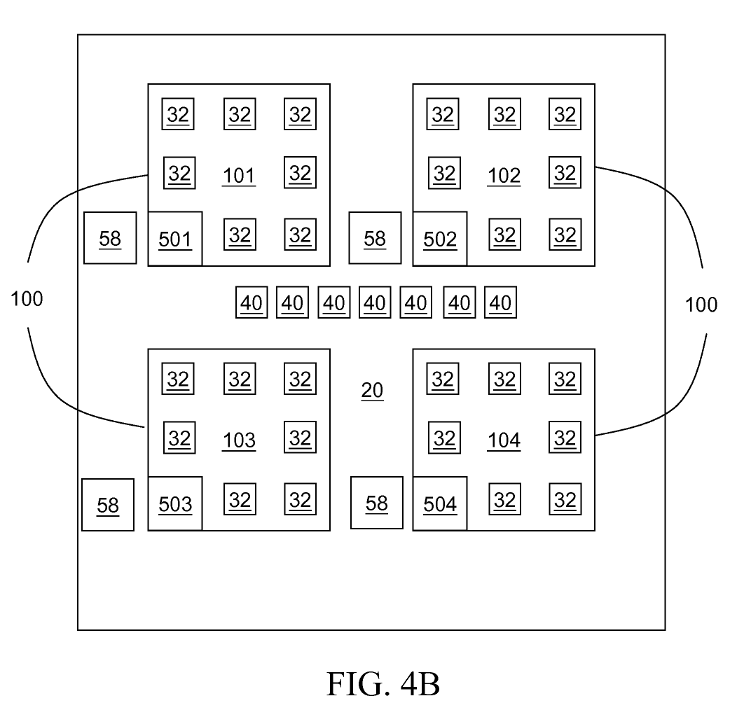

FIGS. 4A and 4B illustrate schematic views of a fast testable wafer according to a third embodiment of the invention. The wafer comprises die groups 100, a scribe line area 20, and testing pads 40.

A die group 100 may comprise a first die 101, a second die 102, a third die 103, and a fourth die 104. The first die 101 comprises a first address decoder 501. The second die 102 comprises a second address decoder 502. The third die 103 comprises a third address decoder 503. The fourth die 104 comprises a fourth address decoder 504. Each die 101, 102, 103, or 104 comprises an electronic switch module 58 and bonding pads 32.

The scribe line area 20 may be interposed between the first die 101, the second die 102, the third die 103, and the fourth die 104, and may be used for separating the first die 101, the second die 102, the third die 103, and the fourth die 104. The scribe line area 20 may be disposed with the testing pads 40.

The first die 101, the second die 102, the third die 103, the fourth die 104 and the testing pads 40 in at least one die group 100 may be connected in at least one of the following two relationships: (1) a part of testing pads 40 may be connected to a plurality of dies; (2) all the testing pads 40 may be connected to the plurality of dies.

In the first connection relationship, the testing pads 40 may be connected to the first die 101, the second die 102, the third die 103, and the fourth die 104 as shown in FIG. 4A. The first die 101, the second die 102, the third die 103, and the fourth die 104 comprise a first group of bonding pads 30 and a second group of bonding pads 31. The first group of bonding pads 30 may not be connected to the testing pads 40. The second group of bonding pads 31 may be electrically connected to the testing pads 40 respectively.

In the second connection relationship, the testing pads 40 may be connected to the first die 101, the second die 102, the third die 103, and the fourth die 104 as shown in FIG. 4B. The first die 101, the second die 102, the third die 103, and the fourth die 104 comprise bonding pads 32. All the bonding pads 32 may be electrically connected to the testing pads 40 respectively.

In the first and second connection relationships, the bonding pads 32 of the first die 101 may be electrically connected to the testing pads 40 through an electronic switch module 58 respectively. The bonding pads 32 of the second die 102, the bonding pads 32 of the third die 103, and the bonding pads 32 of the fourth die 104 may be connected to the testing pads 40 in the same manner. For the simplicity of the drawings, the above connection relations are not shown. One of ordinary skill in the art may select a suitable method to connect the bonding pads 32 and the testing pads 40 according to the concepts disclosed in this embodiment.

In the single embodiment or in some embodiments, the method for selecting dies may comprise: (1) using parallel address decoders; and (2) using serial address decoders.

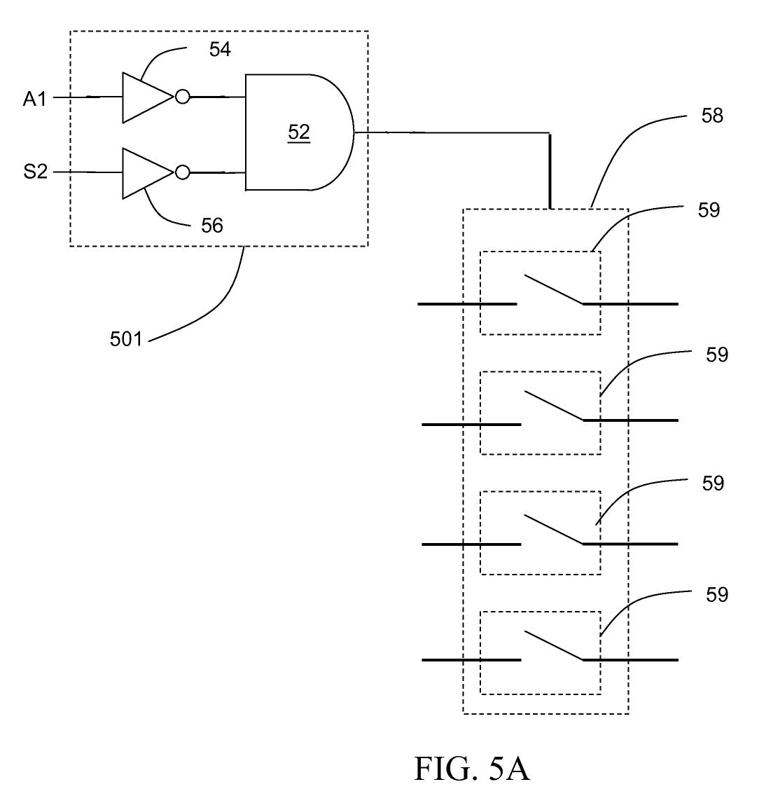

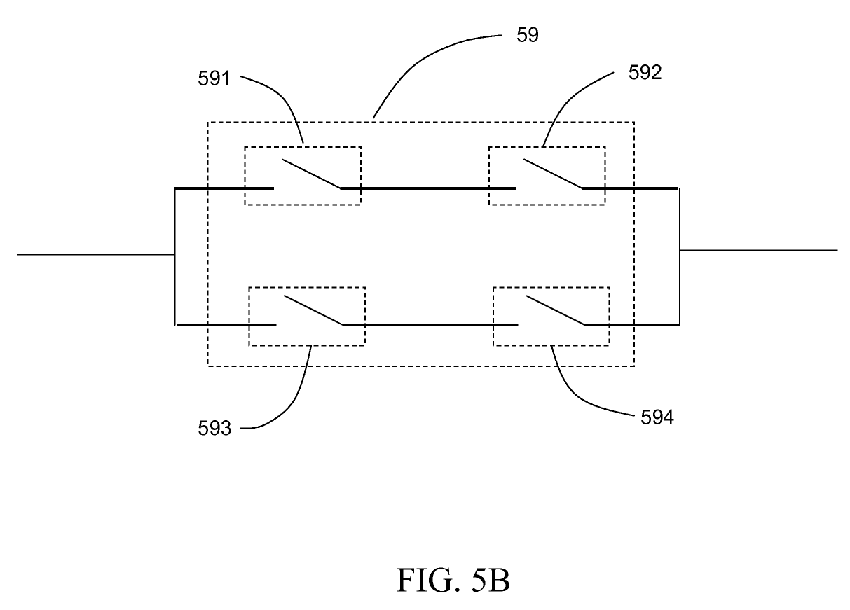

For the first method for selecting dies, FIG. 5A shows a schematic view of connections between the address decoder and the electronic switch module. In FIG. 5A, a first address decoder 501 may be taken as an example. The first address decoder 501 comprises an AND gate 52, a first inverter 54, and a second inverter 56. The AND gate 52 comprises two input. The first inverter 54 may be electrically connected to one input end of the AND gate 52. The second inverter 56 may be electrically connected to the other input end of the AND gate 52. An output of the first address decoder 501 may be electrically connected to the electronic switch module 58, so as to output a signal to control the electronic switch module 58.

In this embodiment, although only the structure of the first address decoder 501 and connection relations between the first address decoder 501 and the electronic switch module 58 may be illustrated, one of ordinary skill in the art may design structures of the second address decoder 502, the third address decoder 503, and the fourth address decoder 504 and the connection relations between the address decoders and the electronic switch modules 58 according to the methods described in this embodiment.

When an address signal may be transmitted to the first address decoder 501, the first address decoder 501 outputs a control signal according to different address signals. In this embodiment, “S1, S2” represent an address signal. The signals S1 and S2 may be “0” or “1”, in which “0” represents low voltage input, and “1” represents high voltage input, for example. The S1 may be transmitted to the first inverter 54. The S2 may be transmitted to the second inverter 56. When the transmitted address signal may be “0, 0”, the output of the AND gate 52 may be “1”. And the electronic switch module 58 may be closed. If the transmitted address signal may be “0, 1”, “1, 0” or “1, 1”, the output of the AND gate 52 may be “0”. At this time, the electronic switch module 58 may be opened.

The second method for selecting dies uses serial address decoders. In the single embodiment or in some embodiments, the first address decoder 501, the second address decoder 502, the third address decoder 503, and the fourth address decoder 504 may be serial address decoders. The serial address decoders may be implemented by some digital circuits with an inter-integrated circuit interface (I2C), or a serial peripheral interface (SPI), or a serial to parallel interface, or other serial interfaces.

In this third embodiment, the first address decoder 501, the second address decoder 502, the third address decoder 503, and the fourth address decoder 504 may be corresponding to different address signals. For example, the address signal corresponding to the first address decoder 501 may be “0, 0”, the address signal corresponding to the second address decoder 502 may be “0, 1”, the address signal corresponding to the third address decoder 503 may be “1, 0”, and the address signal corresponding to the fourth address decoder 504 may be “1, 1”. When the address decoders 501, 502, 503, and 504 receive corresponding address signals, these address decoders 501, 502, 503, and 504 generate a control signal respectively to open or close the electronic switch modules 58.

In the single embodiment or in some embodiments, the electronic switch modules 58 may be in the scribe line area 20 or disposed in the die 10.

The structure of the address decoder as disclosed herein is only for illustrative purposes. One of ordinary skill in the art may design or use a parallel address decoder or a serial address decoder of the same function according to the above input signal and output signal and Boolean algebra related theories.

The address decoder disclosed in this embodiment may be also allowed to receive a group address or a plurality of sub-group addresses. When the address signal comprises a group address or a sub-group address is transmitted, a plurality of address decoders may be selected, and a plurality of electronic switch modules connected thereto may be closed.

FIGS. 5B illustrate schematic views of a fast testable wafer according to structural connection relation of an electronic switch module according to the invention. The electronic switch module 58 may comprise at least one electronic switch assembly 59.

In the single embodiment or in some embodiments, the electronic switch assembly 59 of an electronic switch module 58 related to the same die may be closed or opened at about the same time. With respect to the term “at about the same time”, one of ordinary skill in the art will certainly appreciate the fact that no two switches may practically or scientifically open or close at exactly the same time even though the two switches are designed or intended to open or close at exactly the same time due to the inevitable lag caused by, for example, timing delay or electronic signal transmission delay from or to the two switches.

In the single embodiment or in some embodiments, the electronic switch assembly 59 may be a single electronic switch.

In the single embodiment or in some embodiments, the electronic switch assembly 59 may be a combination of a plurality of electronic switches connected in series and in parallel.

The electronic switch assembly 59 may be a combination of a plurality of electronic switches connected in series and in parallel. The structure of the electronic switch module 58 may be as shown in FIG. 5B. The electronic switch module 58 comprises a first electronic switch 591, a second electronic switch 592, a third electronic switch 593, and a fourth electronic switch 594. The first electronic switch 591 and the second electronic switch 592 may be connected in series to form a first path. The third electronic switch 593 and the fourth electronic switch 594 may be connected in series to form a second path. The first path and the second path may be connected in parallel. The objective of the connection may be to reduce a failure rate of the electronic switch assembly 59.

For example, if a single electronic switch has a, for example, 1% probability of permanent short circuit and a, for example, 1% probability of permanent open circuit. The failure rate after the two switches may be connected in series may be 1.98% in this example. After the two paths may be connected in parallel, the failure rate may be 0.039992% in this example. From the above description, the electronic switch module 58 of this structural design may greatly reduce the failure rate.

In this embodiment, a group having four dies may be taken as an example. However, this may be only for simplicity of the drawings, persons of ordinary skill in the art may use a plurality of dies for a group to implement the invention according to the concepts disclosed in this embodiment.

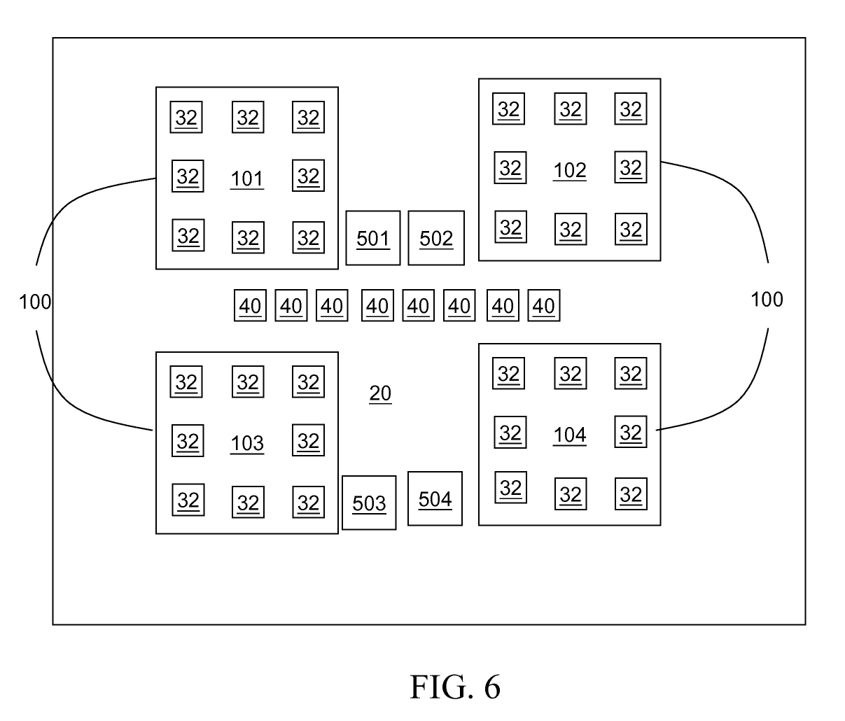

FIG. 6 illustrates a schematic view according to a fourth embodiment of the invention. The wafer comprises die groups 100, a scribe line area 20, and testing pads 40. Apart of the testing pads 40 may be electrically connected to a first address decoder 501, a second address decoder 502, a third address decoder 503, and a fourth address decoder 504. A group of testing probes may transmit address signals through testing pads 40 to select dies to be tested. The first address decoder 501, the second address decoder 502, the third address decoder 503, and the fourth address decoder 504 may be located in the scribe line area 20 or embedded in the dies 10.

For the simplicity of FIG. 6, the connection relations are not shown. Persons of ordinary skill in the art may select a suitable method to electrically connect a part of the testing pads 40 to the first address decoder 501, the second address decoder 502, the third address decoder 503, and the fourth address decoder 504 according to the concepts disclosed in this embodiment.

One of ordinary skill in the art may separate the electronic switch module into a plurality of electronic switches according to the concept disclosed in this embodiment. These electronic switches may be disposed between the electrical paths of the testing pads and the testing points, and may be selected to be closed or opened through the address decoders.

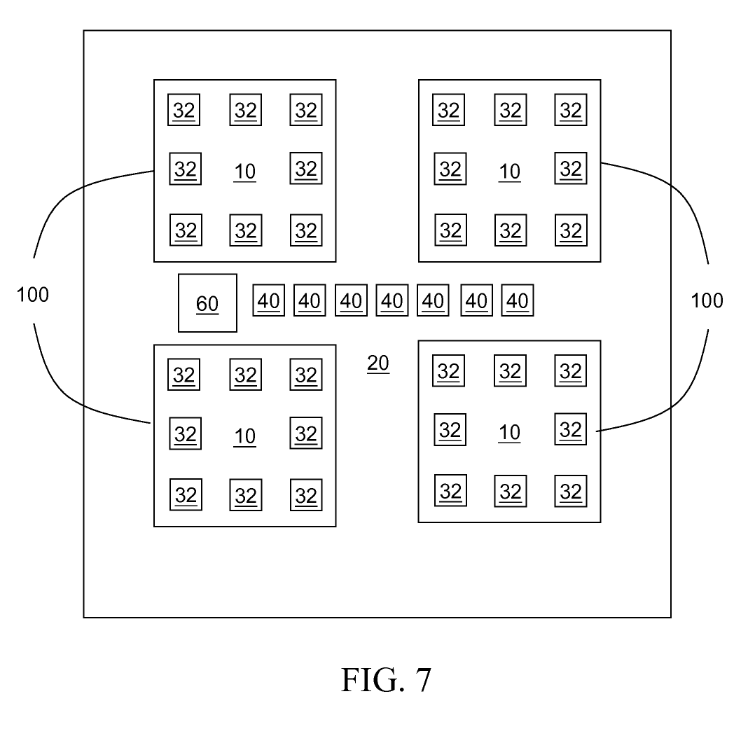

FIG. 7 illustrates a schematic view according to a fifth embodiment of the invention. The wafer comprises a die group 100, a scribe line area 20, and testing pads 40. Apart of the testing pads 40 may be electrically connected to a multiplexer 60. The group of testing probes may select a die to be tested according to an address signal, or a group address signal, or a sub-group address signal through a plurality of the testing pads 40.

For simplicity of FIG. 7, the above connection relations are not shown in FIG. 7. One of ordinary skill in the art may select a suitable method to connect a part of the testing pads 40 to the multiplexer 60 according to the concepts disclosed in this embodiment.

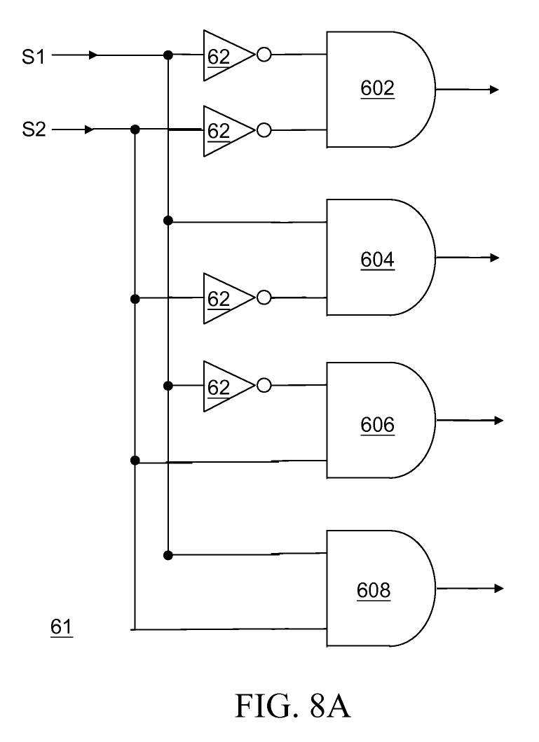

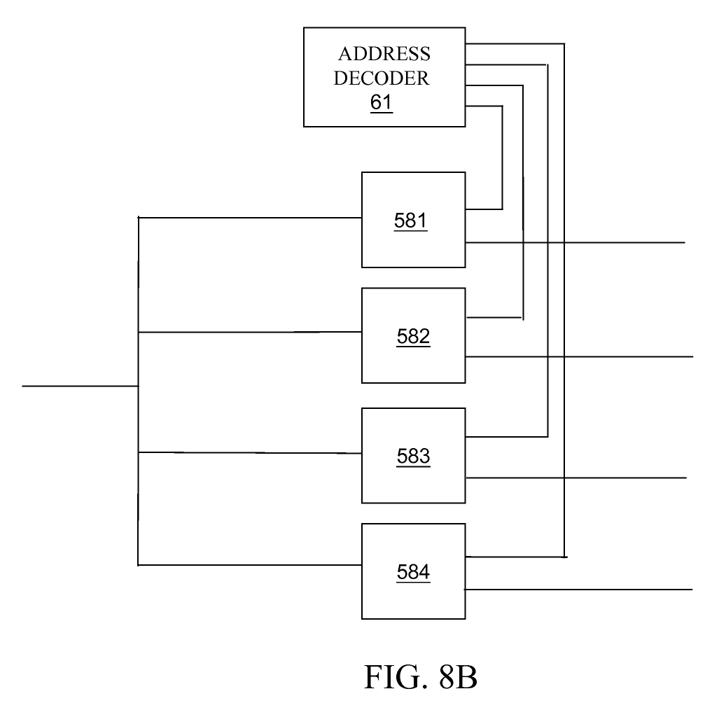

The multiplexer 60 may comprise an address decoder with multiple outputs and a plurality of electronic switch modules. FIG. 8A illustrates a possible circuit schematic view of the address decoder with multiple outputs 61 according to the invention. This address decoder with multiple outputs 61 comprises a first AND gate 602, a second AND gate 604, a third AND gate 606, and a fourth AND gate 608. The first AND gate 602, the second AND gate 604, the third AND gate 606, and the fourth AND gate 608 each have two input. In this embodiment, “S1, S2” represents an address signal. The “S1” may be transmitted to the second AND gate 604 and the fourth AND gate 608, and the “S1” may be transmitted to the first AND gate 602 and the fourth AND gate 608 through an inverter 62. The “S2” may be transmitted to the third AND gate 606 and the fourth AND gate 608, and the “S2” may be transmitted to the first AND gate 602 and the second AND gate 604 through the inverter 62.

FIG. 8B illustrates a view of connections between the address decoder with multiple outputs and the electronic switch module. An output of the address decoder with multiple outputs 61 may be connected to a first electronic switch module 581 of a first die. The address decoder with multiple outputs 61 may generate a plurality of control signals to control the first electronic switch modules 581. The connection may be as shown in FIG. 5A. According to the above connection, the address decoder with multiple outputs 61 may be electrically connected to a second electronic switch module 582 of a second die, a third electronic switch module 583 of a third die, and a fourth electronic switch module 584 of a fourth die.

When the address signal may be “0, 0”, an output signal connected to the first electronic switch module 581 may be “1”, and output signals connected to the second electronic switch module 582, the third electronic switch module 583, and the fourth electronic switch module 584 may be all “0”. At this time, the first electronic switch module 581 may be closed, and the second electronic switch module 582, the third electronic switch module 583, and the fourth electronic switch module 584 may be opened.

As can be seen from the above, when the address signal may be “0, 1”, “1, 0”, and “1, 1”, the second electronic switch module 582, the third electronic switch module 583, and the fourth electronic switch module 584 may be closed respectively. The structure of the multiplexer 60 disclosed in this embodiment may be only for illustrative purposes. One of ordinary skill in the art may design an address multiplexer 60 having the same function according to the above input signal and output signal and Boolean algebra related theories. Lines (connections) among electronic switch modules 581, 582, 583, 584 shown on FIG. 8 are illustrated as single lines, but may represent one or more electrical connection lines.

In the single embodiment or in some embodiments, the testable wafer further comprises at least one isolating element. The isolating element is electrically connected between one of the testing pads 40 and one of the testing points. The isolating element may be an isolator or a buffer amplifier, which will be discussed in detailed in the followings.

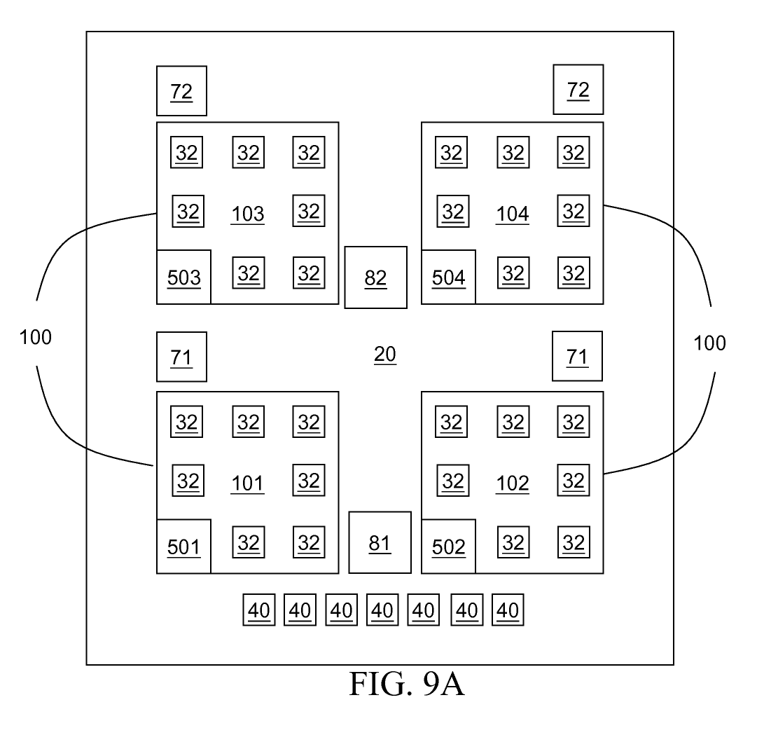

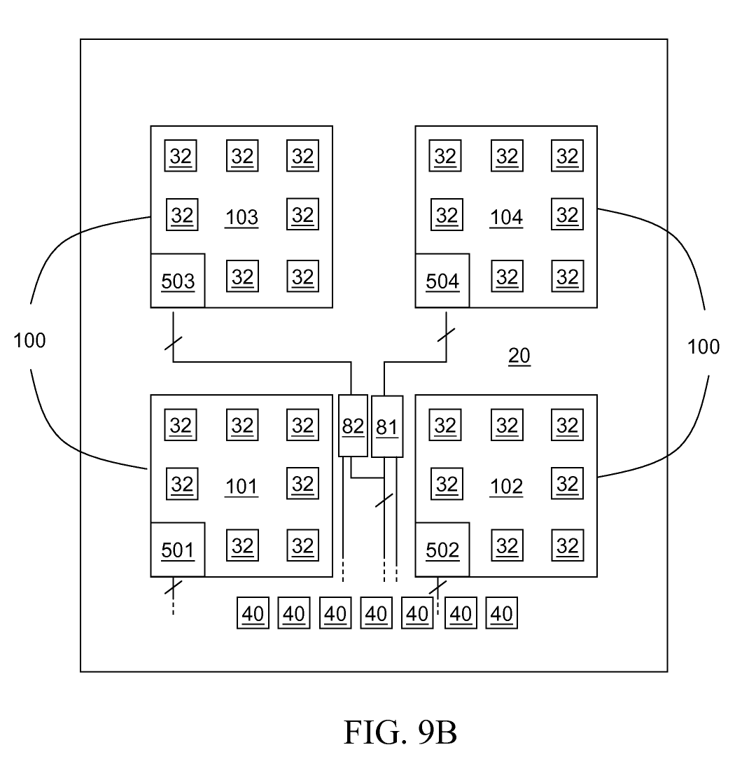

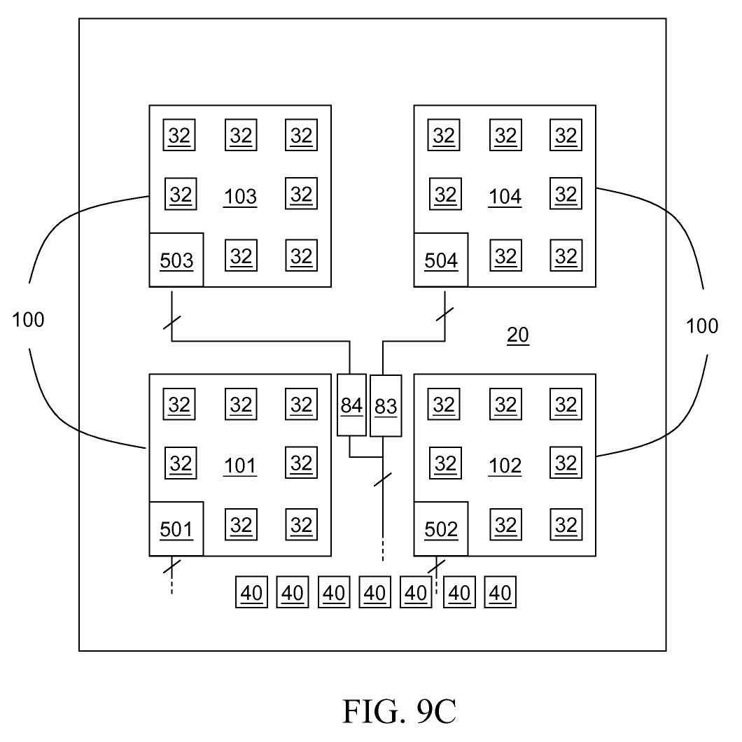

FIG. 9A illustrates a schematic view according to a sixth embodiment of the invention. In this embodiment, the wafer comprises a die group 100, a scribe line area 20, testing pads 40, a first circuit detector 71, a second circuit detector 72, a first isolator 81, and a second isolator 82. The die group 100 comprises a first die 101, a second die 102, a third die 103, and a fourth die 104. The first die 101, the second die 102, the third die 103, and the fourth die 104 comprise the bonding pads 32. The isolators 101,102,103,104 selectively disconnect the connection between the testing pads 40 and the testing points, upon activated.

As process defects may be more likely to appear near the edge of the wafer. When short circuit of a large area occurs, the electrical performance of the parallel circuit may become abnormal. When open circuit of a large area occurs, the decoder may also become ineffective and the whole test may be influenced. The first circuit detector 71 and the second circuit detector 72 may be disposed at a corner of the die. The first isolator 81 and the second isolator 82 may be disposed in an area close to the testing pads 40. The first circuit detector 71 and the second circuit detector 72 may be electrically connected to the first isolator 81 and the second isolator 82 respectively. For example, when the first circuit detector 71 detects that a short circuit or an open circuit in an area of a certain size occurs at or near the edges of a certain die, the first isolator 81 and the second isolator 82 may open the connection(s) between the bonding pads 32 and the testing pads 40 of suitable dies (for example, the first die 101 and the second die 102). Also, the connections closer to the outer edge may be opened (for example, the third die 103 and the fourth die 104) to avoid influences on other part(s) of the test circuit due to failures of a certain die.

In the single embodiment or in some embodiments, a circuit detector detects the process defect at the location of the circuit detector. In the single embodiment or in some embodiments, a circuit detector comprises two parallel metal line sections in the same metal layer. An open of any of these lines or a short between these two lines indicates at least one process defect happened at the location of the circuit detector.

In the single embodiment or in some embodiments, an isolator accepts a control signal to isolate or to electrically connect one or more electrodes of one of its two terminals to the corresponding one or more electrodes of the other terminal. In the single embodiment or in some embodiments, an isolator comprises at least one electrical switch. At least one electrical switch of the isolator may be opened or closed according to at least the control signal.

FIG. 9B illustrates a schematic view according to a seventh embodiment of the invention. In this embodiment, the wafer comprises a die group 100, at least one scribe line area 20, testing pads 40, a first isolator 81, and a second isolator 82. In this embodiment, the isolators may be controlled by the control signals from the testing pads.

FIG. 9C illustrates a schematic view according to an eighth embodiment of the invention. In this embodiment, the wafer comprises a die group 100, a scribe line area 20, testing pads 40, a first group of buffer amplifiers 83, and a second group of buffer amplifiers 84. The buffer amplifiers 83, 84 may prevent the electric circuits connected at the output of the buffer amplifier 83, 84 affect the electric signal at the input of the buffer amplifier 83, 84. In the single embodiment or in some embodiments, the buffer amplifiers 83, 84 comprises two inverters and the output of the first inverter may be electrical connected with the input of the second inverter. In the single embodiment or in some embodiments, the buffer amplifiers 83, 84 may be a unit gain analog amplifier.

In single embodiment or in some embodiments, the testable wafer comprises dies 10, testing pads 40 and at least one isolating element. In another embodiment, the testable wafer comprises dies 10, testing pads 40, at least one electronic switch module 58 and at least one isolating element.

The dies mentioned above may comprise a programmable self-test engine (PSTE). In this kind of embodiment, some of the testing points are electronically connected to the testing pads 40 through the PSTE, while some of the testing points are electronically connected to the testing pads 40 directly. The testing points connected to the testing pads 40 directly can be test by either digital signal or analog signal.

In the single embodiment or in some embodiments, the testable wafer does not have a PSTE. The testing point directly electronically connected to the testing pads 40. Hence, a long test signal can be sent to the testing pads 40 without memory limitation of PSTE. In additional, the test signal from the test instrument (depicted below) to dies 10 maybe either a digital signal or an analog signal.

Regarding above two embodiments (dies with or without PSTE), it is also feasible to have either electronic switch module 58 or isolating element disposed in the connection between the testing pads 40 and the testing points. In the embodiment with both the electronic switch module 58 and the isolating element, the isolating element may be disposed between the testing pads 40 and the electronic switch module 58.

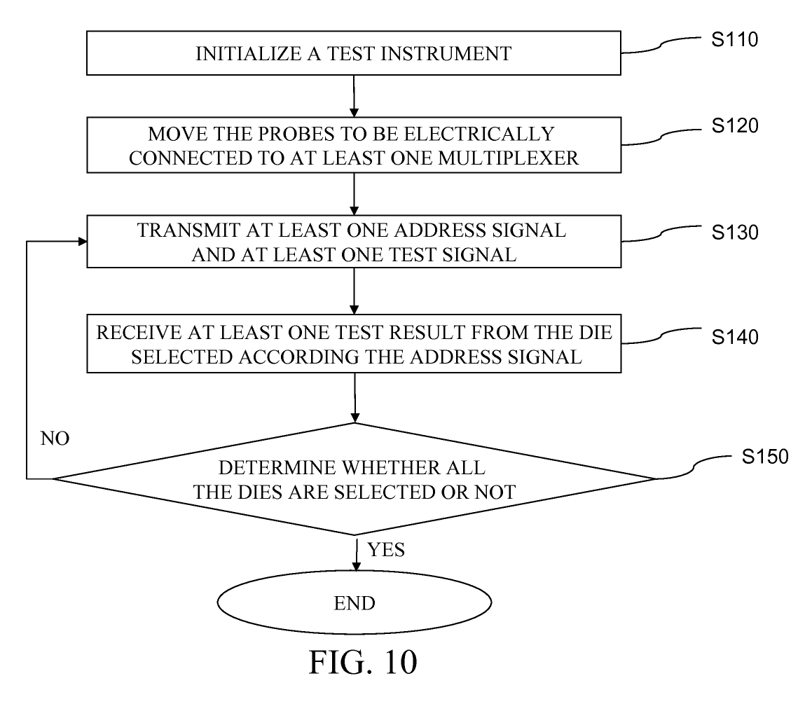

FIG. 10 illustrates a high level block diagram of a test method according to a first embodiment of the test method of the invention. The invention further discloses a wafer test method suitable for testing a wafer. The wafer has a plurality of dies and at least one multiplexer. Each die has a plurality of testing points. The multiplexer has a plurality of inputs and a plurality of outputs. The outputs may be electrically connected to the testing points of at least two dies respectively. The test method comprises the following steps. Initialize a test instrument (S110). The test instrument has a plurality of probes. The probes may be moved to be electrically connected to at least one multiplexer (S120). At least one address signal and at least one test signal may be transmitted to at least one multiplexer (S130). The multiplexer selectively transmits the at least one test signal to the at least one testing point corresponding to the address signal according to the address signal. At least one test result returned from the die selected according the address signal may be received (S140). The test instrument determines whether all the dies may be selected and tested (S150). If some dies may not be selected, Steps (S130) and (S140) may be repeated until all the dies may be selected.

At Step 110, a test instrument may be initialized, the initialization may be known to one of ordinary skill in the art.

At Step 120, the probes may be moved to be electrically connected to input of the multiplexer. The input may be bonding pads or testing pads.

At Step 130, an address signal and at least one test signal may be transmitted to the multiplexer. The address signal may be a parallel address signal or a serial address signal.

At Step 140, a test result returned from the die selected according to the address signal may be received. After a test instrument receives the test result returned from the die, the test result may be compared with a reference signal to determine whether a function of the die may be normal. In a preferred embodiment, the test instrument memorizes addresses of dies having abnormal functions.

At Step 150, in the single embodiment or in some embodiments, the determination method may be ended until the dies in the die.

At Step 150, in the single embodiment or in some embodiments, the determination method may be ended until the dies within the wafer may be all selected.

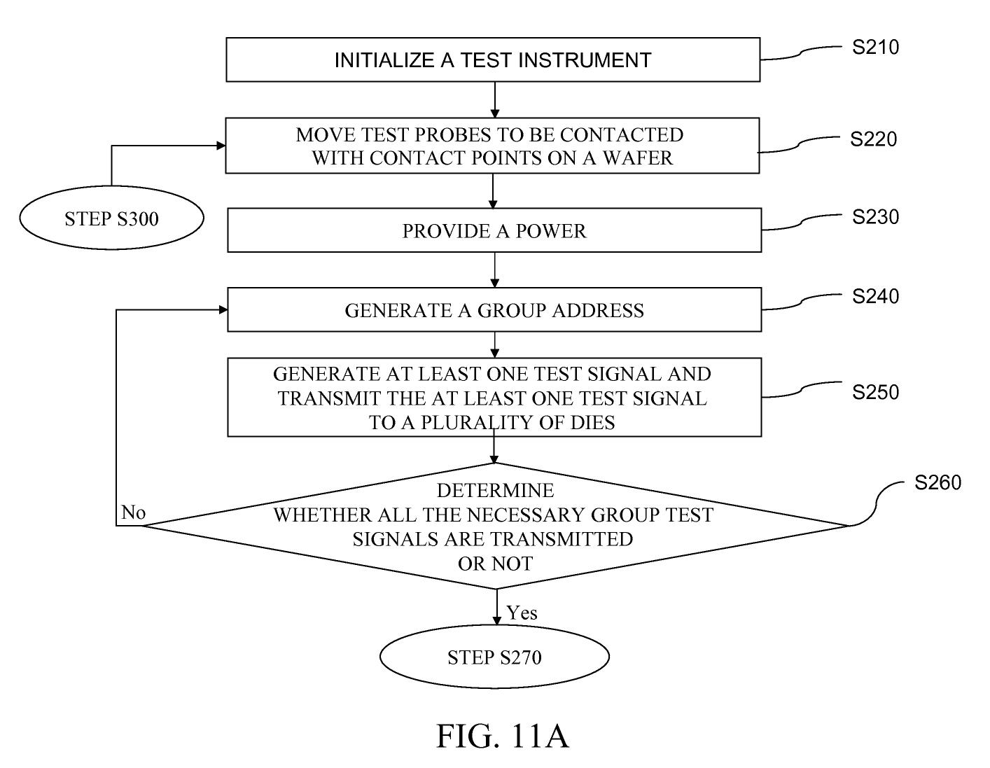

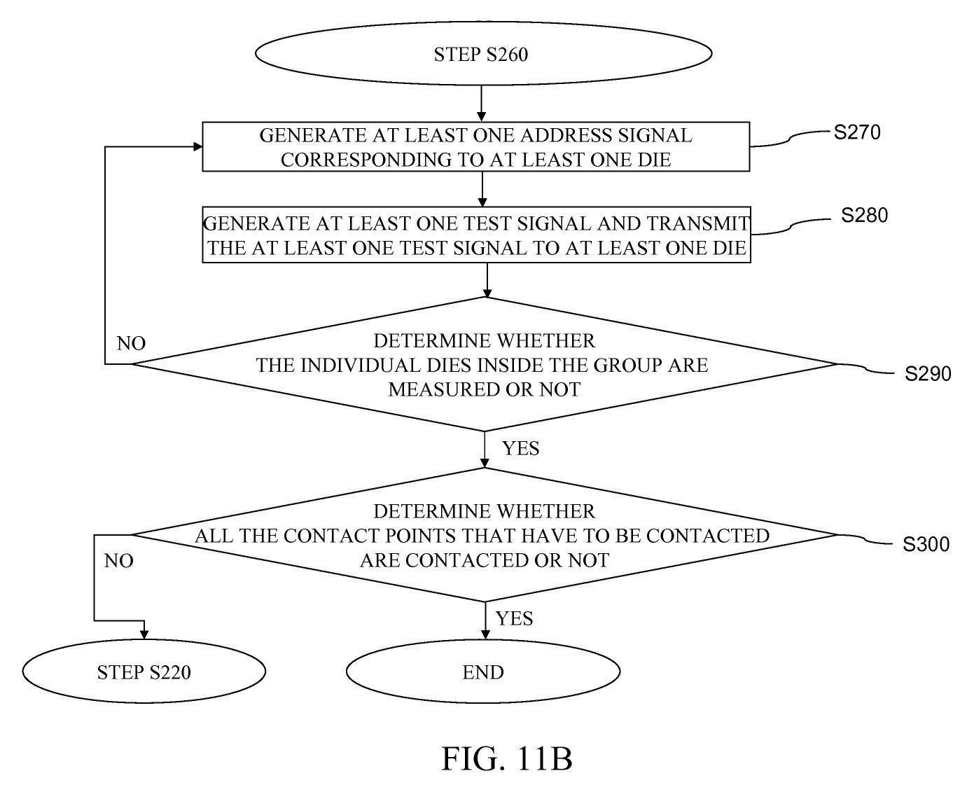

FIGS. 11A and 11B illustrate flow charts of a test method according to a second embodiment of the test method of the invention. Here, a test process may be disclosed. When the tests starts, initialize a test instrument (S210) and load suitable programs. Subsequently, move testing probes to be contacted with contact points on a wafer (S220). At least one of these contact points comprises at least one testing pad in the scribe line area. In a next step, the test instrument provides a power (S230) such that circuits related to the measurement may function as intended. Some measurement may be performed at around this time. Later, the test instrument generates a group address signal (S240) and transmits it to the contact points. The test instrument generates at least one test signal and transmit the at least one test signal to a plurality of dies (S250). The test instrument determines whether the necessary group addresses signals and group test signals may be transmitted (S260). If necessary signals may be still not transmitted, Step S250 may be repeated. After all the necessary group test signals may be transmitted, the test instrument generates at least one address signal corresponding to at least one die (S270). The test instrument generates at least one test signal and transmit at least one test signal to at least one die to test the at least one die (S280). The test instrument determines whether the individual dies inside the group may be measured (S290). If some dies in the group may be still not measured, Step S270 may be repeated until all dies in the group may be measured. The test instrument determines whether all the contact points that have to be contacted may be contacted or not (S300). If some contact points may be still not contacted, Step S220 may be repeated. The probes may be moved to contact a next group of contact points, until all the contact points on the wafer that have to be contacted may be contacted.

In the single embodiment or in some embodiments, at least one contact point may be contacted by a testing probe at Step S220 comprises at least one bonding pad.

In the single embodiment or in some embodiments, the sub-group address may be transmitted from test instrument to testing probes at step S270. A plurality of dies may be tested at step S280.

In the single embodiment or in some embodiments, the method or the apparatus comprises at least one test result received by test instrument after the at least one test signal may be transmitted from test instrument.

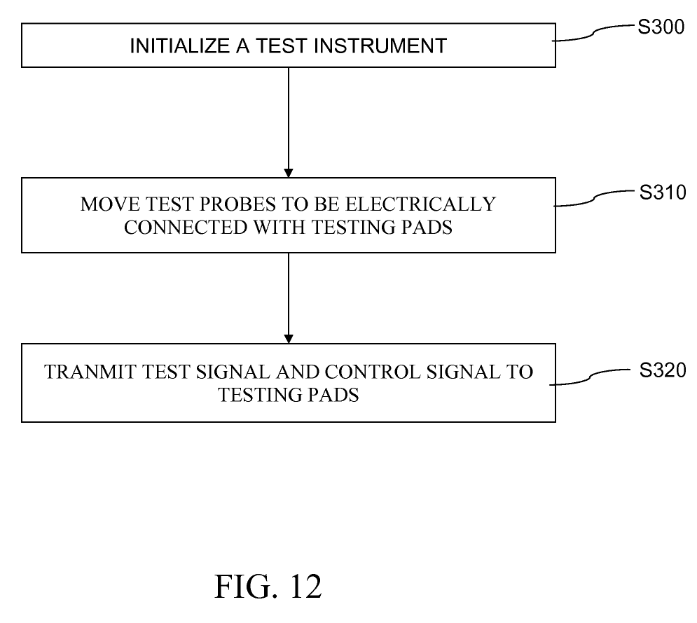

Please refer to FIG. 12 illustrating a flow chart of a test method according to a third embodiment of the test method of the invention. The wafer test method is adapted to testing a wafer. The wafer comprises a plurality of dies, a plurality of testing pads, at least one electronic switch module and a plurality of testing points. At least one of the plurality of testing pads are electrically connected to at least one of the plurality of testing points through the electronic switch module. The wafer test method comprises initializing a test instrument having a plurality of probes (Step S300); moving the probes to be electrically connected to at least one of testing pads (Step S310); and transmitting at least one test signal and at least one control signal to testing pads (Step Page 27 of 36 least one of the testing points in accordance with the control signal. The electronic switch module selectively connects the testing pads with one of the testing points in accordance with the control signal. The test signal may be an analog signal or a digital signal.

The wafer further comprises at least one address decoder which is electrically connected between the electronic switch module and at least one of the testing pads. The wafer test method further comprises receiving the control signal by the address decoder; and controlling the electronic switch module by the address decoder to selectively connect at least one of the testing pads with at least one of the testing points in accordance with the control signal.

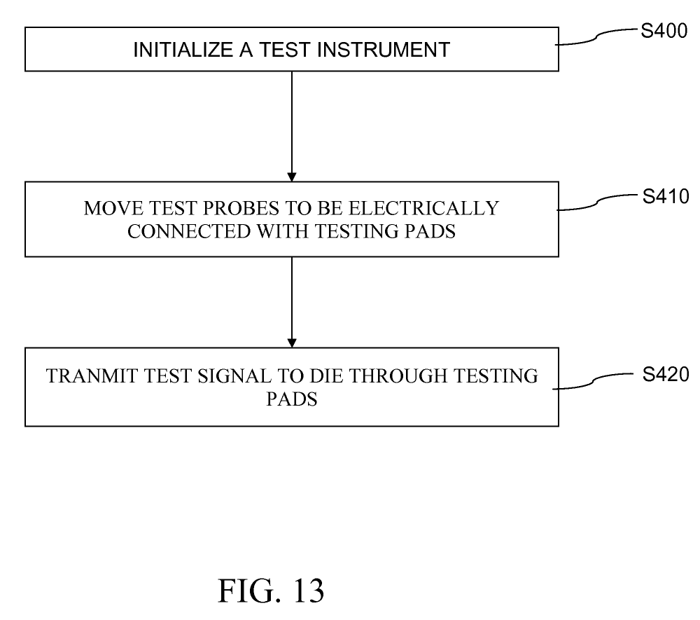

Please refer to FIG. 13 illustrating a flow chart of a test method according to a fourth embodiment of the test method of the invention. The wafer test method is applied for testing a wafer. The wafer comprises a plurality of dies without a programmable self-test engine (PSTE), a plurality of testing pads, and a plurality of testing points, the plurality of testing pads are electrically connected to at least one of the plurality of testing points. The wafer test method comprises initializing a test instrument having a plurality of probes (Step S400); moving the probes to be electrically connected to at least one of testing pads (Step S410); and transmitting at least one test signal to the plurality of dies through at least one of the plurality of testing pads (Step S420). The test signal may be an analog signal or a digital signal.

The wafer further comprises at least one electronic switch module connecting between the plurality of the testing points and the plurality of the testing pads. The wafer test method comprises receiving the control signal by the switch module; and selectively connecting the testing pads with one of testing points of each of the dies.

In the above test process the process for measuring an individual die after a group test signal is transmitted is illustrated as an example, the sequence and repetition times may not be limited to those as illustrated in the example(s). One of ordinary skill in the art may easily achieve the same or similar objectives through different combinations. As a simple example, an individual die may be measured, a group test signal may be transmitted, and then other dies may be measured. As another simple example, the measurement may be performed by transferring a first group test signal and measuring a first individual die followed by transferring a second group test signal and measuring a second individual die, and the like. As yet another simple example, a group test signal may be transmitted before the probes may be moved, so as to write specific information in each die in the group of dies.

In the single embodiment or in some embodiments, the step of transferring the group test signal may be removed. Individual addresses corresponding to individual dies may be generated in sequence, and the measurement of the individual dies may be performed in sequence.

One of ordinary skill in the art may easily measure a plurality of dies in parallel through this method, which will not be further illustrated here for simplicity and also for avoid unnecessary duplication.

In the single embodiment or in some embodiments, specific information needs to be written in a non-volatile memory on a die. One of ordinary skill in the art may easily achieve the objective through the described or similar methods.

In the single embodiment or in some embodiments, wherein no test result need to be received. The test instrument send at least one test signal for testing purpose.

In the single embodiment or in some embodiments, the testable wafer may not have a programmable self-test engine (PSTE). The test signal is transmitting to the dies through the testing pads.

In the above test process the measurement of a plurality of dies may be taken as an example. Persons of ordinary skill in the art may easily place a plurality of address decoders on one die. Therefore, the process may test a plurality of different blocks on the die. Alternatively, the process may also test a plurality of different blocks on a plurality of different dies.

In the single embodiment or in some embodiments, the testing pads and the bonding pads which are not connected to the testing pads may be arranged in an array. The arrangement enables a group of testing probes to measure signals of the wafer conveniently and rapidly. In addition, the invention further discloses a fast testable wafer. The wafer may be disposed with address decoders. When a plurality of dies may be measured, a die to be tested may be selected according to an address signal. Thus, the plurality of dies may be tested without moving the group of testing probes. As the time for mechanically moving group of testing probes may be much longer than that for electrical switching, the time for testing a wafer may be greatly reduced by using the wafer of the invention.

What is claimed is:

1. A fast testable wafer, comprising:
a plurality of dies, comprising a plurality of testing points;
a scribe line area, used for separating at least two of the plurality of dies; and
a plurality of testing pads disposed in the scribe line area, wherein at least one of the plurality of testing points of at least one of the dies is electrically connected to at least one of the plurality of testing pads, the testing pads are arranged in at least one row.

2. The fast testable wafer according to claim 1, wherein at least one testing pad is electrically connected to a plurality of testing points.

3. The fast testable wafer according to claim 1, wherein the plurality of testing points comprises a plurality of bonding pads, and the plurality of testing pads and the plurality of bonding pads are arranged in the plurality of rows.

4. The fast testable wafer according to claim 1, further comprising at least one isolating element electrically connected between at least one of the testing pads and at least one of the testing points.

5. The fast testable wafer according to claim 4, wherein the isolating element is an isolator or a buffer amplifier.

6. A fast testable wafer, comprising:
a plurality of dies, at least one of the dies comprising a plurality of testing points;
an electronic switch module;
a scribe line area used for separating at least two of the plurality of dies; and
a plurality of testing pads disposed in the scribe line area, the switch module, upon activated, selectively connecting at least one of the testing pads with at least one of the testing points.

7. The fast testable wafer according to claim 6, wherein the at least one electronic switch module is controlled by at least one control signals through the at least one of the plurality of testing pads.

8. The fast testable wafer according to claim 6, further comprising at least one address decoder controlling the electronic switch module to selectively connect the plurality of testing points with the plurality of testing pads.

9. The fast testable wafer according to claim 8, wherein the address decoder is a parallel address decoder.

10. The fast testable wafer according to claim 8, wherein the address decoder is a serial address decoder.

11. The fast testable wafer according to claim 6, wherein the electronic switch modules comprises at least one electronic switch assembly, the electronic switch assembly comprise a first electronic switch, a second electronic switch, a third electronic switch, and a fourth electronic switch, the first electronic switch and the second electronic switch are connected in series to form a first path, the third electronic switch and the fourth electronic switch are connected in series to form a second path, and the first path and second path are connected in parallel.

12. The fast testable wafer according to claim 6, further comprising at least one isolating element individually electrically connected between at least one of the testing pads and at least one of the switch modules.

13. The fast testable wafer according to claim 12, wherein the isolating element is an isolator or a buffer amplifier.

14. The fast testable wafer according to claim 6, wherein at least one of the testing pads is electrically connected to at least one of the testing points directly.

15. A wafer test method for testing a wafer, wherein the wafer comprises a plurality of dies, a plurality of testing pads, at least one electronic switch module and a plurality of testing points, at least one of the plurality of testing pads are electrically connected to at least one of the plurality of testing points through the electronic switch module, the wafer test method comprising:
initializing a test instrument having a plurality of probes;
moving the probes to be electrically connected to at least one of testing pads; and
transmitting at least one test signal and at least one control signal to testing pads, the switch module selectively connecting at least one of the testing pads with at least one of the testing points in accordance with the control signal, the electronic switch module selectively connecting at least one of the testing pads with at least one of the testing points in accordance with the control signal.

16. The wafer test method according to claim 15, wherein the wafer further comprises at least one address decoder electrically connected between the electronic switch module and at least one of the testing pads, and the method comprises:
receiving the control signal by the address decoder; and
controlling the electronic switch module by the address decoder to selectively connect at least one of the testing pads with at least one of the testing points in accordance with the control signal.

17. The wafer test method according to claim 15, wherein the test signal comprises an analog signal.

18. A wafer test method for testing a wafer, wherein the wafer comprises a plurality of dies without a programmable self-test engine (PSTE), a plurality of testing pads, and a plurality of testing points, the plurality of testing pads are electrically connected to at least one of the plurality of testing points, the wafer test method comprising:
initializing a test instrument having a plurality of probes;
moving the probes to be electrically connected to at least one of testing pads; and
transmitting at least one test signal to the plurality of dies through at least one of the plurality of testing pads.

19. The wafer test method according to claim 18, wherein the test signal comprises an analog signal.

20. The wafer test method according to claim 19, wherein the wafer further comprises at least one electronic switch module connecting between the plurality of the testing points and the plurality of the testing pads, and the method comprises:
receiving the control signal by the switch module; and
selectively connecting the testing pads with one of testing points of each of the dies.
